(19) United States
(12) Patent Application Publication
(10) Pub. No.: US 2025/0273569 A1
(43) Pub. Date: Aug. 28, 2025

(54) SEMICONDUCTOR DEVICE

(71) Applicant: Samsung Electronics Co., Ltd., Suwon-si (KR)

(72) Inventors: Yeonggil KIM, Suwon-si (KR); Jongmin BAEK, Suwon-si (KR); Kangsub YIM, Suwon-si (KR); Youngwoo CHO, Suwon-si (KR)

(73) Assignee: Samsung Electronics Co., Ltd., Suwon-si (KR)

(21) Appl. No.: 18/924,201

(22) Filed: Oct. 23, 2024

(30) Foreign Application Priority Data
Feb. 23, 2024 (KR) 10-2024-0026664

(51) Int. Cl. H01L 23/528; H01L 29/06; H01L 29/417; H01L 29/423; H01L 29/775; H01L 29/78; H01L 29/786

(52) U.S. Cl. CPC H01L 23/5283; H01L 23/5286; H10D 64/258; H10D 64/518; H10D 30/43; H10D 30/62; H10D 30/6735; H10D 30/6757; H10D 62/121

(57) ABSTRACT

A semiconductor device may include an active region extending in a first direction, a gate structure on the active region and extending in a second direction, a source/drain region on the active region and a side of the gate structure, a contact structure on and electrically connected to the source/drain region, a via structure on and electrically connected to the contact structure, a gate contact structure on and electrically connected to the gate structure, a first signal transmission line structure on the gate structure, and a power transmission line structure on the contact structure. The first signal transmission line structure may include a first line portion extending across the gate structure and a first protrusion portion vertically protruding toward the gate contact structure. The power transmission line structure may include an interconnection portion extending across the gate and contact structures, and an extension portion vertically extending toward the via structure.

### CROSS-REFERENCE TO RELATED APPLICATION(S)

This application claims benefit of priority to Korean Patent Application No. 10-2024-0026664 filed on Feb. 23, 2024 in the Korean Intellectual Property Office, the disclosure of which is incorporated herein by reference in its entirety.

### BACKGROUND

Inventive concepts relate to a semiconductor device.

As demand for implementation of high performance, high speed, and/or multi-functionalization of semiconductor devices increases, a degree of integration of semiconductor devices has been increasing. In manufacturing semiconductor devices having a fine pattern corresponding to the trend for a high degree of integration of semiconductor devices, it may be necessary to implement patterns having a fine width or a fine separation distance.

### SUMMARY

An aspect of inventive concepts provides a semiconductor device including interconnection lines respectively having a step in one direction to limit and/or prevent a short circuit between the interconnection lines.

According to an example embodiment of inventive concepts, a semiconductor device may include a substrate including an active region extending in a first direction; a gate structure on the active region and intersecting the active region, the gate structure including a gate electrode and a gate capping layer on the gate electrode, the gate structure extending in a second direction, the second direction intersecting the first direction; a source/drain region on the active region, the source/drain region on a side of the gate structure; a contact structure on the source/drain region and electrically connected to the source/drain region; a first insulating layer on the gate structure and the contact structure; a gate contact structure passing through the first insulating layer and the gate capping layer of the gate structure, the gate contact structure electrically connected to the gate electrode of the gate structure; a via structure passing through the first insulating layer, the via structure being electrically connected to the contact structure; an etch stop layer on the first insulating layer and the gate contact structure; a second insulating layer on the etch stop layer; an insulating liner on the second insulating layer; and interconnection lines on the first insulating layer, the interconnection lines including a first line, a second line, and a third line sequentially spaced apart in the second direction on the first insulating layer. Each of the first line, the second line, and the third line may include a line portion and an extension portion extending from the line portion in a third direction. In each of the first line, the second line, and the third line, the line portion may pass through the insulating liner and extend in the first direction on the second insulating layer. The third direction may be perpendicular to the first direction and the second direction. The extension portion of the first line, the extension portion of the second line, and the extension portion of the third line each may pass through the second insulating layer and the etch stop layer and may be electrically connected to a corresponding one of the gate contact structure and the via structure.

According to an example embodiment of inventive concepts, a semiconductor device may include a substrate including an active region extending in a first direction; a gate structure on the active region and intersecting the active region, the gate structure extending in a second direction, the second direction intersecting the first direction; a source/drain region on the active region, the source/drain region on a side of the gate structure; a contact structure on the source/drain region and electrically connected to the source/drain region; a via structure on the contact structure and electrically connected to the contact structure; a gate contact structure on the gate structure and electrically connected to the gate structure; a first signal transmission line structure including a first line portion extending in one direction across the gate structure and a first protrusion portion vertically protruding from a lower surface of the first line portion toward the gate contact structure, the first signal transmission line structure being on the gate structure; and a power transmission line structure including an interconnection portion and an extension portion, the interconnection portion extending in the one direction across the gate structure and the contact structure, and the extension portion vertically extending from a lower surface of the interconnection portion toward the via structure, the power transmission line structure being on the contact structure.

According to an example embodiment of inventive concepts, a semiconductor device may include a substrate including an active region extending in a first direction; a gate structure on the active region and intersecting the active region, the gate structure including a gate electrode and a gate capping layer on the gate electrode, the gate structure extending in a second direction, the second direction intersecting the first direction; a source/drain region on the active region, the source/drain region on a side of the gate structure; a contact structure on the source/drain region and electrically connected to the source/drain region; a first insulating layer on the gate structure and the contact structure; a gate contact structure passing through the first insulating layer and the gate capping layer of the gate structure, the gate contact structure electrically connected to the gate electrode of the gate structure; a via structure passing through the first insulating layer, the via structure electrically connected to the contact structure; an etch stop layer on the first insulating layer and the gate contact structure; a second insulating layer on the etch stop layer; an insulating liner on the second insulating layer; and first interconnection lines on the first insulating layer and spaced apart from each other in the second direction. The first interconnection lines may include a first line structure and a second line structure The first line structure may include a first line portion and a protrusion portion. The first line portion may be on the second insulating layer and extend in one direction across the gate structure. The protrusion portion may vertically protrude from a lower surface of the first line portion, pass through the second insulating layer and the etch stop layer, and may be in contact with the gate contact structure. The second line structure may include an interconnection portion and an extension portion. The interconnection portion may be on the second insulating layer and may extend in the one direction across the gate structure and the contact structure. The extension portion may vertically protrude from a lower surface of the interconnection portion, pass through the second insulating layer and the etch stop layer, and may be in contact with the via structure. Outer peripheries of the protrusion portion of the first line structure and the extension portion of the second line structure may have a circular cross-section.

### BRIEF DESCRIPTION OF DRAWINGS

The above and other aspects, features, and advantages of inventive concepts will be more clearly understood from the following detailed description, taken in conjunction with the accompanying drawings, in which:

FIG. 1 is a plan view of a semiconductor device according to an example embodiment;

FIG. 2 is a cross-sectional view of a semiconductor device according to example embodiments;

FIG. 3 is a partially enlarged view of a semiconductor device according to example embodiments;

FIG. 4 is a cross-sectional view of a semiconductor device according to example embodiments;

FIG. 5 is a partially enlarged view of a semiconductor device according to example embodiments;

FIG. 6 is a cross-sectional view of a semiconductor device according to example embodiments;

FIGS. 7 to 11 are partially enlarged views of a semiconductor device according to example embodiments;

FIG. 12 is a cross-sectional view of a semiconductor device according to example embodiments; and

FIGS. 13 to 22 are vertical cross-sectional views of sequential processes of a method of manufacturing a semiconductor device according to an example embodiment.

### DETAILED DESCRIPTION

Hereinafter, example embodiments of inventive concepts are described with reference to specific example embodiments and accompanying drawings.

Inventive concepts may, however, be embodied in many different forms and should not be construed as being limited to the specific example embodiments set forth herein. In addition, example embodiments of inventive concepts may be provided for a more complete description of inventive concepts to those skilled in the art. Accordingly, the shapes and sizes of the elements in the drawings may be exaggerated for clarity of description, and elements denoted by the same reference numerals in the drawings may be the same elements.

The terminology used herein is for the purpose of describing particular example embodiments only and is not to be limiting of the example embodiments. As used herein, the singular forms “a,” “an,” and “the” are intended to include the plural forms as well, unless the context clearly indicates otherwise. It will be further understood that the terms “comprises” and/or “comprising,” when used in this code, specify the presence of stated features, integers, steps, operations, elements, components or a combination thereof, but do not preclude the presence or addition of one or more other features, integers, steps, operations, elements, components, and/or groups thereof. As used herein, the term “and/or” includes any one and any combination of any two or more of the associated listed items.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

It will be understood that, although the terms “first,” “second,” “third,” and the like may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of inventive concepts.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

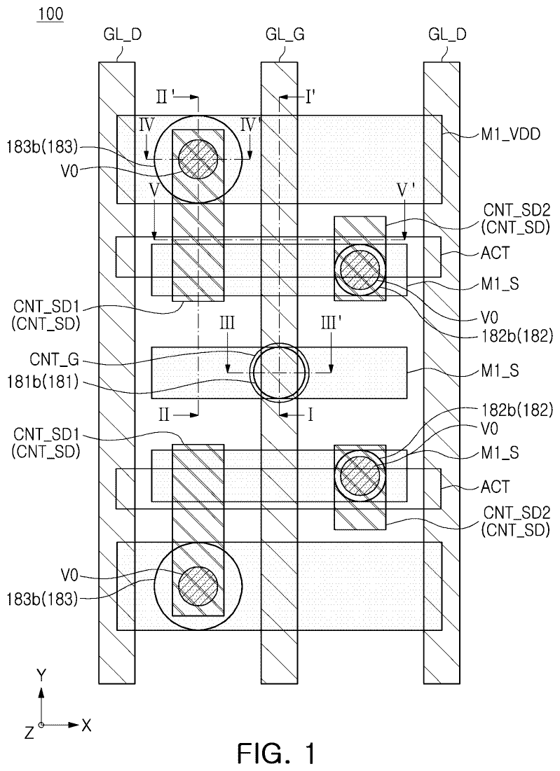

FIG. 1 is a plan view of a semiconductor device according to an example embodiment. FIG. 1 may be a plan view of a region corresponding to a standard cell, among cells included in a semiconductor device.

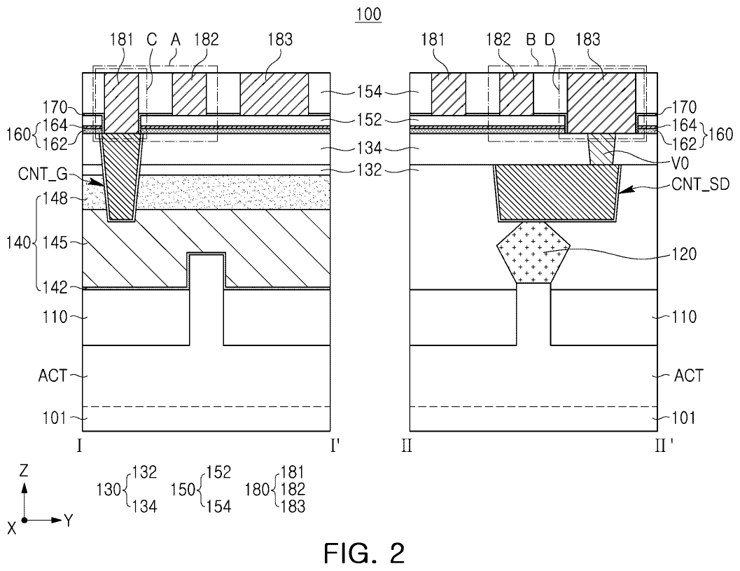

FIG. 2 is a cross-sectional view of a semiconductor device according to example embodiments. FIG. 2 illustrates cross-sections of the semiconductor device of FIG. 1, taken along lines I-I′ and II-II′.

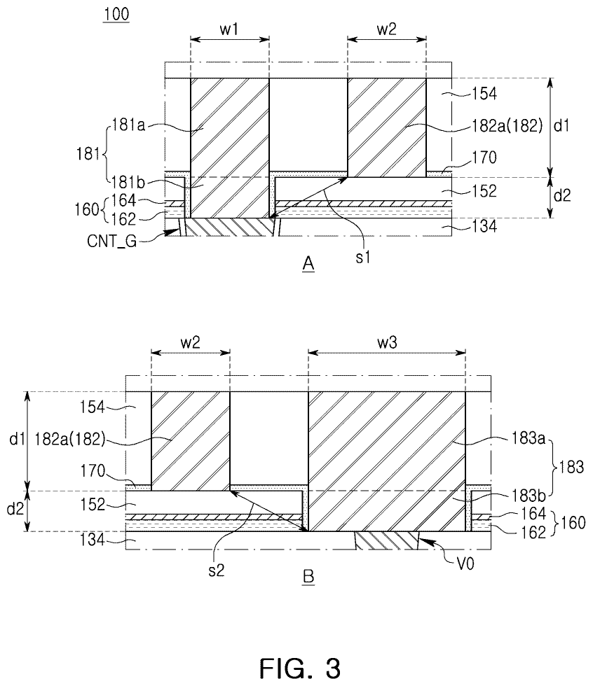

FIG. 3 is a partially enlarged view of a semiconductor device according to example embodiments. FIG. 3 illustrates partially enlarged views of region “A” and region “B” of FIG. 2.

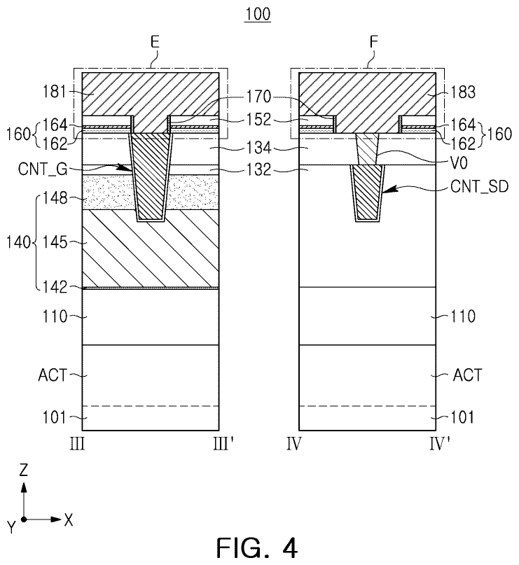

FIG. 4 is a cross-sectional view of a semiconductor device according to example embodiments. FIG. 4 illustrates cross-sections of the semiconductor device of FIG. 1, taken along lines III-III' and IV-IV′

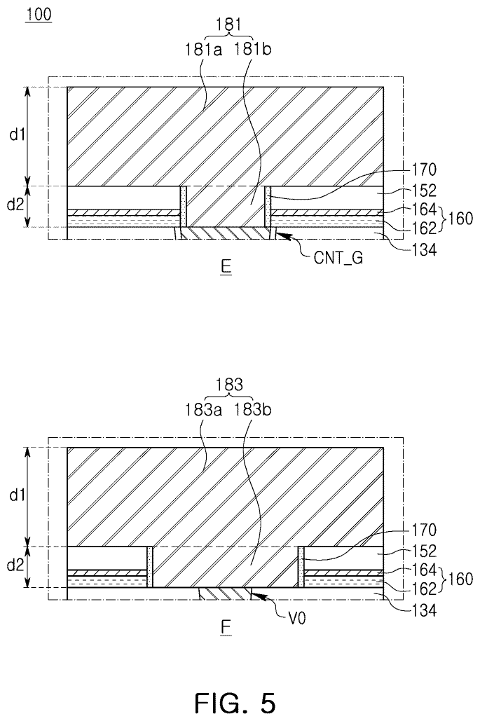

FIG. 5 is a partially enlarged view of a semiconductor device according to example embodiments. FIG. 5 illustrates partially enlarged views of region “E” and region “F” of FIG. 4.

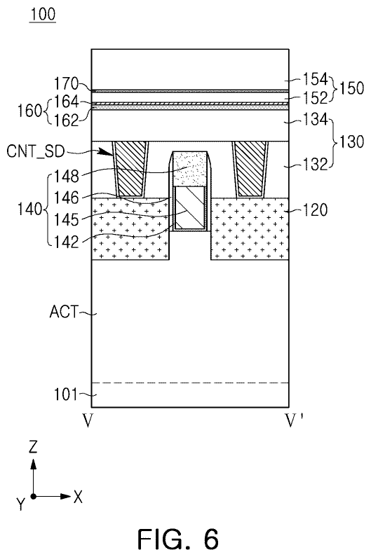

FIG. 6 is a cross-sectional view of a semiconductor device according to example embodiments. FIG. 6 illustrates cross-sections of the semiconductor device of FIG. 1, taken along line V-V′.

For ease of description, FIGS. 1 to 6 illustrate only some components of the semiconductor device.

Referring to FIGS. 1 to 6, a semiconductor device 100 may include a substrate 101, an active region ACT extending in a first direction (for example, an X-direction), gate lines GL extending in a second direction (for example, a Y-direction), contact structures CNT connected to the active regions ACT and the gate lines GL, lower vias V0 connected to the contact structures CNT, and first interconnection lines M1 connected to the lower vias V0. The semiconductor device 100 may further include device isolation layers 110, a lower interlayer insulating layer 130, a plurality of upper interlayer insulating layers 150, at least one etch stop layer 160, and a liner 170. In some example embodiments, the semiconductor device 100 may further include second interconnection lines disposed on upper portions of the first interconnection lines M1, the second interconnection lines electrically connecting the first interconnection lines M1 to each other.

The substrate 101 may have an upper surface extending in the X-direction and the Y-direction. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

The device isolation layers 110 may define active fins in the substrate 101. The device isolation layers 110 may be formed of an insulating material. The device isolation layers 110 may be formed using, for example, a shallow trench isolation (STI) process. The device isolation layers 110 may be, for example, oxide, nitride, or a combination thereof.

The active regions ACT may be defined by, for example, the device isolation layers 110 within the substrate 101, and may include one or more active fins extending in the first direction, for example, the X-direction. The active fins may have a structure of an active fin protruding from the substrate 101. The active fins may be formed as part of the substrate 101, or may include an epitaxial layer grown from the substrate 101. However, on a side surface of the gate structure 140, the active fins on the substrate 101 may be recessed and source/drain regions 120 may be disposed.

The source/drain regions 120 may be disposed on the active region ACT, on opposite sides of the gate structure 140. The source/drain regions 120 may serve as a source region or a drain region of the semiconductor device 100. The source/drain regions 120 may be in the form of an elevated source/drain having an upper surface, positioned to be higher than a lower surface of the gate structure 140, but inventive concepts are not limited thereto. For example, the upper surface of each of the source/drain regions 120 may be positioned to be lower than the lower surface of the gate structure 140 (not illustrated). In the present example embodiment, the source/drain regions 120 are illustrated as having a pentagonal shape, but the source/drain regions 120 may have various shapes, for example, one shape among a polygonal shape, a circular shape, and a rectangular shape. In addition, in the present example embodiment, the source/drain regions 120 are illustrated as being disposed on a single active fin, but inventive concepts are not limited thereto. For example, the source/drain regions 120 may be connected or merged to each other on multiple active fins (not illustrated). The source/drain regions 120 may include, for example, silicon or silicon germanium (SiGe).

The gate lines GL extend in the second direction, for example, the Y-direction, and may be disposed to be spaced apart from each other in the first direction, for example, the X-direction (FIG. 1). The gate lines GL may include gate electrodes GL_G and dummy gate electrodes GL_D, providing a semiconductor device. For example, the gate lines GL_G, disposed on edges (or boundaries) of a standard cell region, may be the dummy gate electrodes GL_D.

The gate structures 140 may be disposed on an upper portion of the active region ACT to intersect the active fins and to extend in the second direction, for example, the Y-direction (FIG. 2). The gate structures 140 may be disposed to correspond to the gate electrodes GL_G of FIG. 1. The gate structure 140 may include a gate dielectric layer 142, a gate electrode layer 145, gate spacer layers 146, and a gate capping layer 148.

The gate dielectric layer 142 may be disposed between the active region ACT and the gate electrode layer 145. The gate dielectric layer 142 may include oxide, nitride, or a high-κ material. The high-κ material may refer to a dielectric material having a dielectric constant, higher than that of a silicon oxide film (SiO₂).

The gate electrode layer 145 may be disposed on the gate insulating layer 142. The gate electrode layer 145 may include a conductive material, for example, a metal nitride such as titanium nitride (TiN), tantalum nitride (TaN), or tungsten nitride (WN), and/or a metal material such as aluminum (Al), tungsten (W), or molybdenum (Mo) or a semiconductor material such as doped polysilicon. The gate electrode layer 145 may include two or more multiple layers.

The gate spacer layers 146 may be disposed on opposite side surfaces of the gate electrode layer 145. The gate spacer layers 146 may insulate the source/drain regions 120 and the gate electrode layer 145 from each other. The gate spacer layers 146 may have a multilayer structure in some example embodiments. The gate spacer layers 146 may be formed of oxide, nitride, and oxynitride. In particular, the gate spacer layers 146 may be formed of a low-κ film. For example, the gate spacer layers 146 may include at least one of SiO, SiN, SiCN, SiOC, SiON, and SiOCN.

The gate capping layer 148 may be disposed on an upper portion of the gate electrode layer 145, and may have a lower surface and side surfaces, respectively surrounded by the gate electrode layer 145 and the gate spacer layers 146. The gate capping layer 148 may be formed of, for example, oxide, nitride, and oxynitride.

Lower interlayer insulating layers 130 may include a first lower interlayer insulating layer 132 covering the source/drain regions 120 and the gate structures 140, and a second lower interlayer insulating layer 134 disposed on the first lower interlayer insulating layer 132. The first and second lower interlayer insulating layers 132 and 134 may be distinct layers in a process, and the first and second lower interlayer insulating layers 132 and 134 may be formed of a single layer (not illustrated). The lower interlayer insulating layer 130 may include, for example, at least one of oxide, nitride, and oxynitride, and may include a low-κ material.

Source/drain contact structures CNT_SD (or “contact structures”) may pass through the first lower interlayer insulating layer 132 to be connected to the source/drain regions 120, and may apply an electrical signal to the source/drain regions 120. The source/drain contact structures CNT_SD may be disposed to recess the source/drain regions 120 to a desired (and/or alternatively predetermined) depth, but inventive concepts are not limited thereto. The source/drain contact structures CNT_SD may include a conductive material, for example, a metal material such as tungsten (W), aluminum (Al), copper (Cu), or a semiconductor material such as doped polysilicon. In some example embodiments, the source/drain contact structures CNT_SD may include a barrier metal layer disposed along an external surface thereof. In addition, in some example embodiments, the source/drain contact structures CNT_SD may further include a metal-semiconductor layer, such as a silicide layer, disposed at an interface thereof in contact with the source/drain regions 120. The source/drain contact structure CNT_SD, disposed on one side of the gate structure 140 and electrically connected to the third line structure 130, may be referred to as a first source/drain contact structure CNT_SD1. In addition, the source/drain contact structure CNT_SD, disposed on the other side of the gate structure 140, opposite to the one side of the gate structure 140 and electrically connected to the second line structure 120, may be referred to as a second source/drain contact structure CNT_SD2.

The lower vias V0 (or “lower via structures”) may pass through the lower interlayer insulating layers 130 to be connected to the source/drain contact structures CNT_SD. For example, the lower vias V0 may pass through a second lower interlayer insulating layer 164 to be electrically connected to the source/drain contact structure CNT_SD. The lower vias V0 may include a conductive material, for example, a metal material such as tungsten (W), aluminum (Al), or copper (Cu), or a semiconductor material such as doped polysilicon. In some example embodiments, the lower vias V0 may further include a barrier metal layer disposed along an external surface thereof (not illustrated).

The gate contact structures CNT_G may pass through the lower interlayer insulating layers 130 to be connected to the gate structures 140. For example, the gate contact structures CNT_G may pass through the first and second lower interlayer insulating layers 132 and 134 and the gate capping layer 148 to be electrically connected to the gate electrode layer 145. The gate contact structures CNT_G may include a conductive material, for example, a metal material such as tungsten (W), aluminum (Al), copper (Cu), or a semiconductor material such as doped polysilicon. In some example embodiments, the gate contact structures CNT_G may include a barrier metal layer disposed along an external surface thereof.

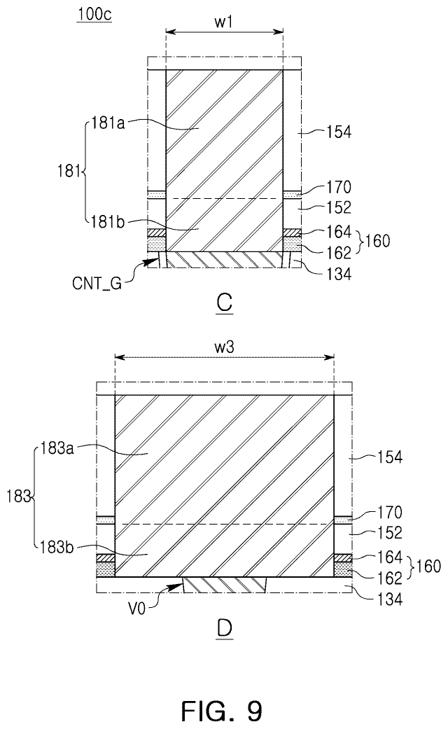

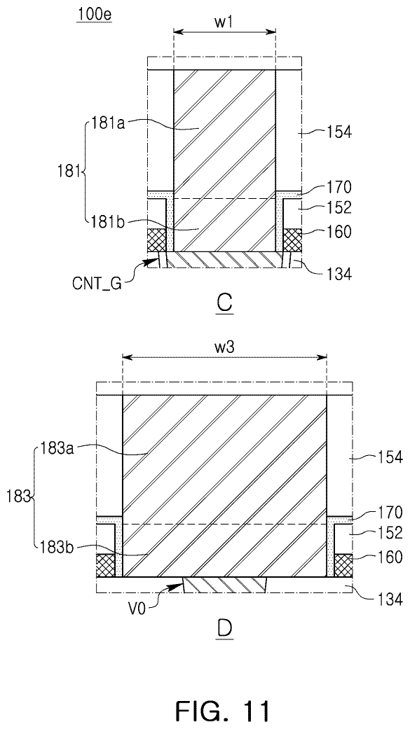

Etch stop layers 160 may be disposed on the lower interlayer insulating layers 130. The etch stop layers 160 may be disposed on, for example, the second lower interlayer insulating layer 134. The etch stop layers 160 may function as an etch stop layer in an etch process for forming the first interconnection lines M1. The etch stop layers 160 may include at least one of a high-κ material, such as aluminum oxide (Al₂O₃), aluminum nitride (AlN), hafnium oxide (HfO₂), zirconium oxide (ZrO₂), and silicon oxycarbide (SIOC), and combinations thereof. A first etch stop layer 162 and a second etch stop layer 164 on the first etch stop layer 162 may be selected from the group consisting of the above-described high-κ materials, and the first and second etch stop layers 162 and 164 may include different materials. According to an example embodiment, the etch stop layer 160 may be formed of a single layer (see FIGS. 9 and 11).

The upper interlayer insulating layers 150 may include first and second upper interlayer insulating layers 152 and 154, sequentially disposed on the etch stop layers 160. The upper interlayer insulating layer 150 may be formed of silicon oxide or a low-κ material. The upper interlayer insulating layer 150 may include, for example, at least one of SiO, SIN, SiCN, SiOC, SiON, and SiOCN.

The liner 170 may be disposed between the first and second upper interlayer insulating layers 152 and 154. The liner 170 may function as an etch stop layer in an etching process for forming the first interconnection lines M1. The liner 170 may include a high-κ material, for example, at least one of aluminum oxide (Al₂O₃), aluminum nitride (AlN), hafnium oxide (HfO₂), and zirconium oxide (ZrO₂). Accordingly, the liner 170 may be referred to as an insulating liner.

The first interconnection lines M1 may be interconnections disposed on upper portions of the active regions ACT and the gate lines GL, and may extend in the X-direction (FIG. 1). The first interconnection lines M1 may include a first power transmission line M1_VDD, a second power transmission line M1_VSS, and signal transmission lines M1_S. The first power transmission line M1_VDD and the second power transmission line M1_VSS may be power transmission lines respectively supplying different power voltages (VDD and VSS) to a semiconductor device, and may be electrically connected to source/drain regions on the active regions ACT. The signal transmission lines M1_S may be signal transmission lines supplying a signal to the semiconductor device, and may be electrically connected to the gate electrode GL_G.

First interconnection lines 180 may be interconnections disposed on the upper portions of the active regions ACT and the gate lines GL (FIG. 2), and the first interconnection lines 180 may be disposed to correspond to the first interconnection lines M1 of FIG. 1.

The first interconnection lines 180 may include first to third line structures 181, 182, and 183 disposed to extend in the first direction (X-direction) and to be spaced apart from each other in the second direction (Y-direction). The first and second line structures 181 and 182 may be components corresponding to the signal transmission lines M1_S. Accordingly, the first line structure 181 may be referred to as a first signal transmission line structure, and the second line structure 182 may be referred to as a second signal transmission line structure. The third line structure 183 may be a component corresponding to the first power transmission line M1_VDD or the second power transmission line M1_VSS.

Referring to FIGS. 1, 3, and 5, each of the first to third line structures 181, 182, and 183 may include a line portion (or “interconnection portion”) extending in the first direction (X-direction), and an extension portion (or “protrusion portion”) extending vertically downwardly from at least a portion of a lower surface of the line portion.

The first line structure 181 may include a first line portion 181a extending in the first direction (X-direction) across the gate structure 140 at the top of the gate structure 140, and a first extension portion 181b vertically extending from at least a portion of a lower surface of the first line portion 181a toward the gate structure 140, on the gate structure 140.

The first line portion 181a may be defined as a component passing through at least a portion of the second upper interlayer insulating layer 154 and the insulating liner 170, and extending in the first direction (X-direction) from an upper surface of the first upper interlayer insulating layer 152.

The first extension portion 181b may be defined as a component vertically downwardly protruding from at least a portion of the lower surface of the first line portion 181a toward the gate structure 140. Accordingly, the first extension portion 181b may be referred to as a first protrusion portion. The first extension portion 181b may pass through the first upper interlayer insulating layer 152 and the etch stop layers 162 and 164, and may have a lower surface in contact with an upper surface of the gate contact structure CNT_G. A horizontal width of the lower surface of the first extension portion 181b in the second direction (Y-direction) may be substantially equal to a horizontal width of the upper surface of the gate contact structure CNT_G in the second direction (Y-direction), but inventive concepts are not limited thereto.

The first line portion 181a and the first extension portion 181b may include the same conductive material. Accordingly, the lower surface of the first line portion 181a and an upper surface of the first extension portion 181b may not be distinguished from each other in terms of a boundary therebetween. The first line portion 181a and the first extension portion 181b may include, for example, at least one of aluminum (Al), copper (Cu), and tungsten (W). In inventive concepts, the first line portion 181a and the first extension portion 181b may include copper (Cu).

A first vertical thickness d1 of the first line portion 181a may be greater than a second vertical thickness d2 of the first extension portion 181b. A ratio of the first vertical thickness d1 and the second vertical thickness d2 may be 2:1 or more, for example, 2:1 to 6:1, or 3:1 to 5:1.

The third line structure 183 may include a third line portion 183a extending in the first direction (X-direction) across the gate structure 140 and the source/drain contact structure CNT_SD at the top of the gate structure 140, and a third extension portion 183b vertically extending from at least a portion of a lower surface of the third line portion 183a toward a via structure V0, on the source/drain contact structure CNT_SD.

The third line portion 183a may be defined as a component passing through at least a portion of the second upper interlayer insulating layer 154 and the insulating liner 170, and extending in the first direction (X-direction) from the upper surface of the first upper interlayer insulating layer 152.

The third extension portion 183b may be defined as a component extending vertically downwardly from at least a portion of the lower surface of the third line portion 183a toward the via structure V0. The third extension portion 183b may pass through the first upper interlayer insulating layer 152 and the etch stop layers 162 and 164, and may have a lower surface in contact with an upper surface of the via structure V0. A horizontal width of a lower surface of the third extension portion 183b in the second direction (Y-direction) may be greater than a horizontal width of the upper surface of the via structure V0 in the second direction (Y-direction).

The third line portion 183a and the third extension portion 183b may include the same conductive material. Accordingly, a lower surface of the first line portion 183a and an upper surface of the third extension portion 183b may not be distinguished from each other in terms of a boundary therebetween. For example, the third line portion 183a and the third extension portion 183b may include at least one of aluminum (Al), copper (Cu), and tungsten (W). In inventive concepts, the third line portion 183a and the third extension portion 183b may include copper (Cu).

A vertical thickness of the third line portion 183a may be substantially equal to the first vertical thickness d1 of the first line portion 181a. Similarly, a vertical thickness of the third extension portion 183b may be substantially equal to the second vertical thickness d2 of the first extension portion 181b. Accordingly, a ratio of the vertical thickness of the third line portion 183a and the vertical thickness of the third extension portion 183b may correspond to the first vertical thickness d1 of the first line portion 181a and the second vertical thickness d2 of the first extension portion 181b.

The second line structure 182 may be disposed between the first line structure 181 and the third line structure 183, and may extend in the first direction (X-direction) across the gate structure 140 and the source/drain contact structure CNT_SD at the top of the gate structure 140.

In a similar manner to the first line structure 181 and the third line structure 183, the second line structure 182 may also include a second line portion 182a extending in the first direction (X-direction) across the gate structure 140 and the source/drain contact structure CNT_SD at the top of the gate structure 140, and a second extension portion 182b vertically extending from at least a portion of a lower surface of the second line portion 182a toward the via structure V0, on the source/drain contact structure CNT_SD (see FIGS. 1 and 3).

Here, the second extension portion 182b of the second line structure 182 and the third extension portion 183b of the third line structure 183 may be positioned on opposite sides of the gate structure 140. For example, the second extension portion 182b of the second line structure 182 may be positioned on one side of the gate structure 140, and the third extension portion 183b of the third line structure 183 may be positioned on the other side of the gate structure 140, opposite to the one side of the gate structure 140.

The second line portion 182a may be defined as a component passing through at least a portion of the second upper interlayer insulating layer 154 and the insulating liner 170, and extending in the first direction (X-direction) from the upper surface of the first upper interlayer insulating layer 152.

The second extension portion 182b may be defined as a component vertically downwardly protruding from at least a portion of the lower surface of the second line portion 182a toward the via structure V0. The second extension portion 182b may pass through the first upper interlayer insulating layer 152 and the etch stop layers 162 and 164, and may have a lower surface in contact with an upper surface of the source/drain contact structure CNT_SD. A horizontal width of the lower surface of the second extension portion 182b in the second direction (Y-direction) may be substantially equal to a horizontal width of the upper surface of the via structure V0 in the second direction (Y-direction).

The second line portion 182a and the second extension portion 182b may include the same conductive material. Accordingly, the lower surface of the second line portion 182a and an upper surface of the second extension portion 182b may not be distinguished from each other in terms of a boundary therebetween. The second line portion 182a and the second extension portion 182b may include, for example, at least one of aluminum (Al), copper (Cu), and tungsten (W). In inventive concepts, the second line portion 182a and the second extension portion 182b may include copper (Cu).

In at least one cross-sectional view, among a plurality of cross-sectional views extending in the second direction (Y-direction), the plurality of cross-sectional views in the third direction (Z-direction), levels of lowermost surfaces of the first to third line structures 181, 182, and 183 may be different from each other.

For example, in a first cross-sectional view extending in the second direction, the first cross-sectional view in a third direction overlapping the upper surface of the gate contact structure CNT_G, among the third directions, the lowermost surface of the first line structure 181 may be on a level, lower than those of the lowermost surface of the second line structure 182 and/or the lowermost surface of the third line structure 183 (see the cross-section taken along I-I′ of FIG. 3). Such a configuration may be due to the first extension portion 181b of the first line structure 181. Accordingly, a level difference between the lowermost surface of the first line structure 181, and the lowermost surfaces of the second line structure 182 and/or the third line structure 183 may be the vertical thickness d2 of the first extension portion 181b.

According to inventive concepts, a sufficient separation distance s1 may be secured between the first line structure 181 and the second line structure 182, adjacent to each other. Here, the separation distance s1 may be defined as a minimum distance between an outer periphery of the lowermost surface of the first line structure 181 and an outer periphery of the lowermost surface of the second line structure 182. The sufficient secured separation distance s1 may be achieved by the first extension portion 181b of the first line structure 181.

Accordingly, a short circuit that may occur between the second line structure 182 and the gate contact structure CNT_G, positioned on a lower portion of the first line structure 181, may be limited and/or prevented and/or minimized.

In addition, in a second cross-sectional view extending in the second direction, the second cross-sectional view in a third direction overlapping an upper surface of the first source/drain contact structure CNT_SD1, among the third directions, the lowermost surface of the third line structure 183 may be on a level, lower than those of the lowermost surfaces of the first line structure 181 and/or the second line structure 182 (see the cross-sections taken along II-II′ of FIGS. 1 and 3). Such a configuration may be due to the third extension portion 183b of the third line structure 183. Accordingly, a level difference between the lowermost surface of the third line structure 183 and the lowermost surfaces of the first line structure 181 and/or the second line structure 182 may be the vertical thickness d2 of the third extension portion 183b.

Accordingly, a sufficient separation distance s2 may be secured between the second line structures 182 and the third line structures 183, adjacent to each other. Here, the separation distance s2 may be defined as a minimum distance between an outer peripheral surface of the lowermost surface of the second line structure 182 and an outer peripheral surface of the lowermost surface of the third line structure 183. The sufficient secured separation distance s2 may be achieved by the third extension portion 183b of the third line structure 183.

Accordingly, a short circuit that may occur between the second line structure 182 and the source/drain contact structure CNT_SD, positioned on a lower portion of the third line structure 183, may be limited and/or prevented and/or minimized.

In addition, a vertical depth of the third extension portion 183b of the third line structure 183 in the third direction (Z-direction) may be secured without risk to the short circuit.

Although not illustrated, in a third cross-sectional view extending in the second direction, the third cross-sectional view in a third direction overlapping an upper surface of the second source/drain contact structure CNT_SD2, among the third directions, the lowermost surface of the second line structure 182 may be on a level, lower than those of the lowermost surfaces of the first line structure 181 and/or the third line structure 183. Such a configuration may be due to the second extension portion 182b of the second line structure 182 (see FIG. 1).

Referring to FIGS. 1, 4, and 5, the first extension portion 181b of the first line structure 181, the second extension portion 182b of the second line structure 182, and the third extension portion 183b of the third line structure 183 may have a cylindrical shape. In other words, outer peripheries of the first extension portion 181b, the second extension portion 182b, and the third extension portion 183b may have a circular cross-section.

A horizontal width of the outer periphery of the first extension portion 181b may be substantially equal to a first horizontal width w1 of the first line portion 181a in the second direction (Y-direction). Similarly, a horizontal width of the outer periphery of the second extension portion 182b may be substantially equal to a second horizontal width w2 of the second line portion 182a in the second direction (Y-direction). Here, the first and second horizontal widths w1 and w2 may be substantially equal to each other, but inventive concepts are not limited thereto.

Similarly, a horizontal width of the outer periphery of the third extension portion 183b may be substantially equal to a third horizontal width w3 of the third line portion 183a in the second direction (Y-direction). Here, the third horizontal width w3 may be greater than the first and second horizontal widths w1 and w2.

Referring back to FIGS. 2 and 3, the insulating liner 170 may extend along a side surface of an extension portion of each of the first to third line structures 181, 182, and 183.

For example, the insulating liner 170 may be in contact with a side surface of a lower region of the first line portion 181a, and may vertically downwardly extend along a side surface of the first extension portion 181b and a side surface of a first upper insulating layer 152 (see the cross-section taken along I-I′ in FIG. 2 and FIG. 3).

In addition, the insulating liner 170 may be in contact with a side surface of a lower region of the third line portion 183a, and may vertically downwardly extend along a side surface of the third extension portion 183b and the side surface of the first upper insulating layer 152 (see the cross-section taken along II-II′ in FIG. 2 and FIG. 3).

Although not illustrated, at least a portion of the insulating liner 170 may be in contact with a side surface of a lower region of the second line portion 182a, and may vertically downwardly extend along a side surface of the second extension portion 182b and the side surface of the first upper insulating layer 152.

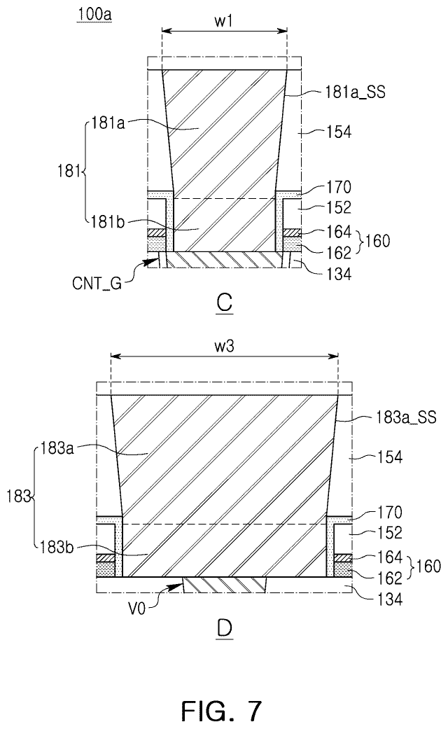

FIGS. 7 to 11 are partially enlarged views of a semiconductor device according to example embodiments.

Referring to FIG. 7, a semiconductor device 100a may be the same as or similar to that illustrated in FIGS. 1 to 6, except that upper regions of first to third line structures 181, 182, and 183 have a tapering structure.

Referring to FIG. 7, at least a portion of a side surface 181a_SS of a first line portion 181a may include a portion inclined with respect to a lower surface of the first line portion 181a. In other words, a horizontal width w1 of the first line portion 181a in a second direction (Y-direction) may gradually decrease as a distance to a first extension portion 181b decreases.

Similarly, a horizontal width w3 of a third line portion 183a of the third line structure 183 in the second direction (Y-direction) may also gradually decrease as a distance to a third extension portion 183b decreases. Although not illustrated, the above-described features may be applied to the second line structure in the same manner.

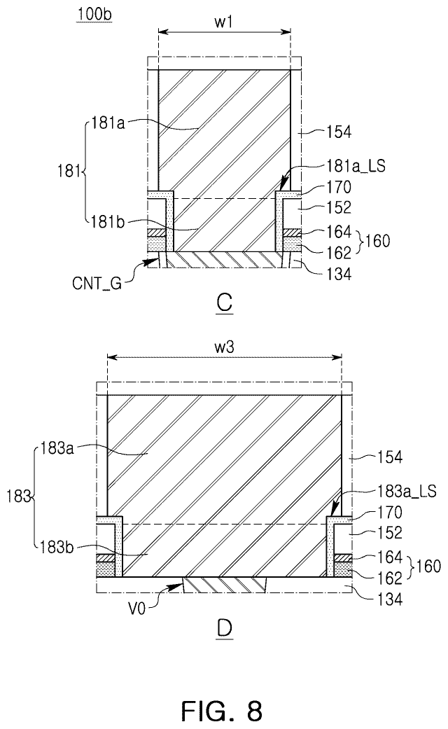

Referring to FIG. 8, a semiconductor device 100b may be the same as or similar to that illustrated in FIGS. 1 to 6, except that upper regions of first to third line structures 181, 182, and 183 have a step.

Referring to FIG. 8, a lower surface 181a_LS of a first line portion 181a may have a step. For example, at least a portion of the lower surface 181a_LS of the first line portion 181a may be in contact with at least a portion of an upper surface of an insulating liner 170.

Similarly, a lower surface 183a_LS of a third line portion 183a may have a step. For example, at least a portion of the lower surface 183a_LS of the third line portion 183a may be in contact with at least a portion of the upper surface of the insulating liner 170. Although not illustrated, the above-described features may be applied to the second line structure in the same manner.

Referring to FIG. 9, a semiconductor device 100c may be the same as or similar to those illustrated in FIGS. 1 to 8, except that an insulating liner 170 is in contact with only side surfaces of first to third line structures 181, 182, and 183.

Referring to FIG. 9, the insulating liner 170 may be in contact with only side surfaces of lower regions of first and third line portions 181a and 183a of the first and third line structures 181 and 183, on a first upper interlayer insulating layer 152. In another view, the insulating liner 170 may not extend to a space between first and third extension portions 181b and 183b of the first and third line structures 181 and 183 and the first upper interlayer insulating layer 152. Although not illustrated, the above-described features may be applied to the second line structure in the same manner.

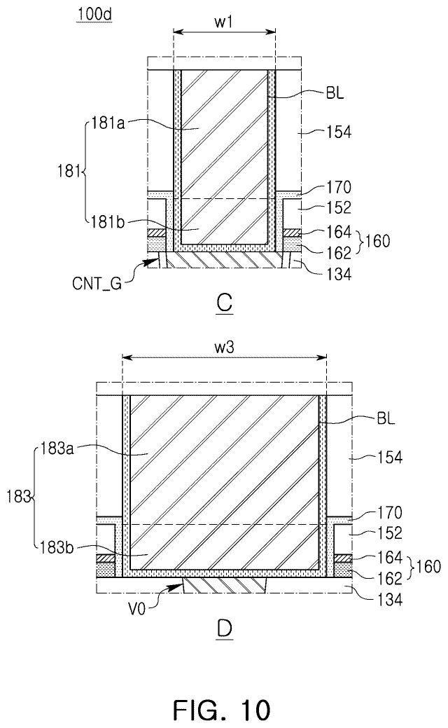

Referring to FIG. 10, a semiconductor device 100d may be the same as or similar to those illustrated in FIGS. 1 to 8, except that the semiconductor device 100d further includes a barrier layer BL disposed along external surfaces of conductive material layers of the first to third line structures 181, 182, and 183.

Referring to FIG. 10, the barrier layer BL may be additionally disposed on at least a portion of external surfaces of the first and third line structures 181 and 183. For example, the barrier layer BL may be disposed on side surfaces of first and third line portions 181a and 183a, and may extend to cover side surfaces and lower surfaces of the first and third extension portions 181b and 183b. The barrier layer BL may include at least one of titanium (Ti), tantalum (Ta), cobalt (Co), titanium nitride (TiN), and tantalum nitride (TaN). Although not illustrated, the above-described features may be applied to the second line structure in the same manner.

Referring to FIG. 11, a semiconductor device 100e may be the same or similar to those described with reference to FIGS. 1 to 9, except that an etch stop layer 160 is a single layer.

Referring to FIG. 11, the etch stop layer 160 between a second lower interlayer insulating layer 134 and a first upper interlayer insulating layer 152 may be a single layer. The etch stop layer 160 may include a material the same as or similar to that of the etch stop layer 160 described with reference to FIGS. 1 to 6.

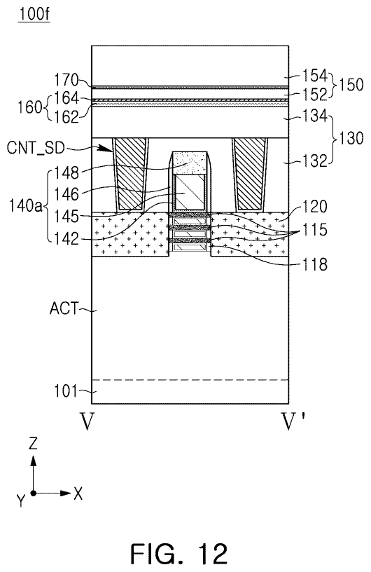

FIG. 12 is a cross-sectional view of a semiconductor device according to example embodiments. FIG. 12 illustrates a schematic cross-section of the semiconductor device of FIG. 1, taken along line V-V′.

Referring to FIG. 12, a semiconductor device 100f may further include a plurality of channel layers 115 disposed on an active regions ACT to be vertically spaced from each other, and internal spacer layers 118 disposed between the plurality of channel layers 115 to be parallel to a gate electrode layer 145. The semiconductor device 100f may include transistors having a gate-all-around structure in which a gate structure 140a is disposed between an active fin and the channel layers 115 and between the plurality of channel layers 115 having a nano sheet shape. For example, the semiconductor device 100f may include transistors having a multi-bridge-channel FET (MBCFETTM) structure, formed by the channel layers 115, source/drain regions 120, and the gate structure 140a.

The plurality of channel layers 115 may be disposed on the active fin as two or more layers disposed to be spaced apart from each other in a direction, perpendicular to an upper surface of the active fin, for example, a Z-direction. The channel layers 115 may be connected to the source/drain regions 120, and may be spaced apart from an upper surface of an active fin 105. The channel layers 115 may have a width equal to or similar to that of the active fin in a Y-direction, and may have a width equal to or similar to that of the gate structure 140a in an X-direction. However, in some example embodiments, the channel layers 115 may have a reduced width such that side surfaces of the channel layers 115 are positioned on a lower portion of the gate structure 140a in the X-direction.

The plurality of channel layers 115 may be formed of a semiconductor material, and may include, for example, at least one of silicon (Si), silicon germanium (SiGe), and germanium (Ge). For example, the channel layers 115 may be formed of a material the same as that of as the substrate 101. In example embodiments, the number and shape of the channel layers 115, included in a single channel structure, may be changed in various manners. For example, in some example embodiments, a channel layer may be further positioned in a region in which active fins 105 are in contact with the gate electrode layer 145.

The gate structure 140a may be disposed on upper portions of the active fins 105 and the plurality of channel layers 115, and may extend to intersect the active fins 105 and the plurality of channel layers 115. Channel regions of transistors may be formed in the active fins 105 and the plurality of channel layers 115, intersecting the gate structure 140a. In present example embodiment, a gate insulating layer 142 may be disposed not only between the active fin 105 and the gate electrode layer 145, but also between the plurality of channel layers 115 and the gate electrode layer 145. The gate electrode layer 145 may be disposed on upper portions of the active fins 105 to extend to the upper portions of the plurality of channel layers 115 while filling a space between the plurality of channel layers 115. The gate electrode layer 145 may be spaced apart from the plurality of channel layers 115 by the gate insulating layer 142.

The internal spacer layers 118 may be disposed between the plurality of channel layers 115 to be parallel to the gate electrode layer 145. The gate electrode layer 145 may be spaced apart from the source/drain regions 120 by the internal spacer layers 118 to be electrically isolated from the source/drain regions 120. The internal spacer layers 118 may have a flat side surface opposing the gate electrode layer 145, or may have an inwardly convex rounded shape toward the gate electrode layer 145. The internal spacer layers 118 may be formed of oxide, nitride, and oxynitride. In particular, the internal spacer layers 118 may be formed of a low-κ film.

In example embodiments, the semiconductor device 100f having the MBCFETTM structure may be disposed in one region of the semiconductor device described above with reference to FIGS. 7 to 11. In addition, in example embodiments, at least one region of the semiconductor device may include a vertical FET including an active region extending to be perpendicular to an upper surface of a substrate 101 and a gate structure disposed to surround the active region.

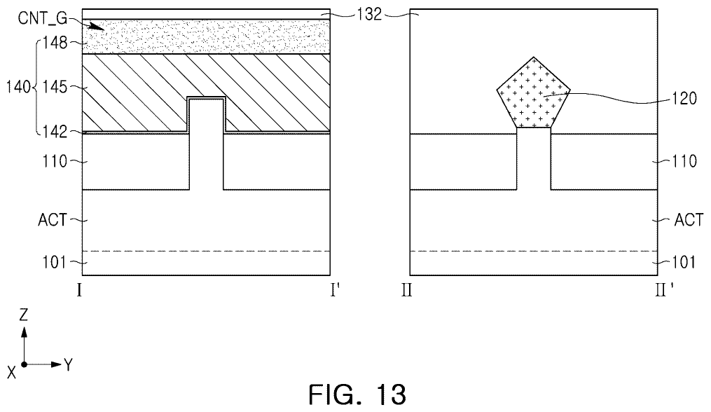

FIGS. 13 to 22 are vertical cross-sectional views of sequential processes of a method of manufacturing a semiconductor device according to an example embodiment.

FIGS. 13 to 15 may be process diagrams of sequential processes of forming a middle of line (MOL) of the semiconductor device 100 according to an example embodiment.

Referring to FIG. 13, a substrate 101, a device isolation layer 110 defining an active region ACT, on the substrate 101, a gate structure 140 on the active region ACT, a source/drain region 120 formed on at least one side of the gate structure 140, on the active region ACT, and a first lower interlayer insulating layer 132 covering the gate structure 140 and the source/drain region 120.

The device isolation layer 110 may be formed by patterning the substrate 101 to form a desired (and/or alternatively predetermined) trench defining an active fin, and then filling the trench with an insulating material. Thereafter, a portion of the insulating material may be removed to allow an upper region of the active fin to protrude toward the substrate 101.

Thereafter, a dummy gate insulating layer and a dummy gate electrode, extending to intersect the active fin, may be sequentially stacked, and then a spacer 146 may be formed on opposite sides of the dummy gate insulating layer and the dummy gate electrode (see the spacer 146 in FIG. 6). Subsequently, a portion of the active fin may be selectively removed from opposite sides of the spacer 146.

Subsequently, referring to FIG. 6, the source/drain region 120 may be formed on the recessed active fin on the opposite sides of the spacer 146. The source/drain region 120 may be formed using, for example, a selective epitaxial growth (SEG) process. The source/drain region 120 may be grown along a crystallographically stable surface during the growth process, and thus may have a pentagonal or hexagonal shape, as illustrated. However, a size and shape of the source/drain region 120 are not limited to those illustrated in the drawings.

Thereafter, the dummy gate insulating layer and the dummy gate electrode may be removed to sequentially form a gate insulating layer 142, a gate electrode layer 145, and a gate capping layer 148, and then the first lower interlayer insulating layer 132, covering the gate structure 140 and the source/drain region 120, may be formed.

After the first lower interlayer insulating layer 132 is first formed, a planarization process may be performed on an upper surface of the dummy gate electrode, and then the dummy gate insulating layer and the dummy gate electrode may be removed to form the gate structure 140. In this case, the first lower interlayer insulating layer 132 may not be disposed on the gate structure 140.

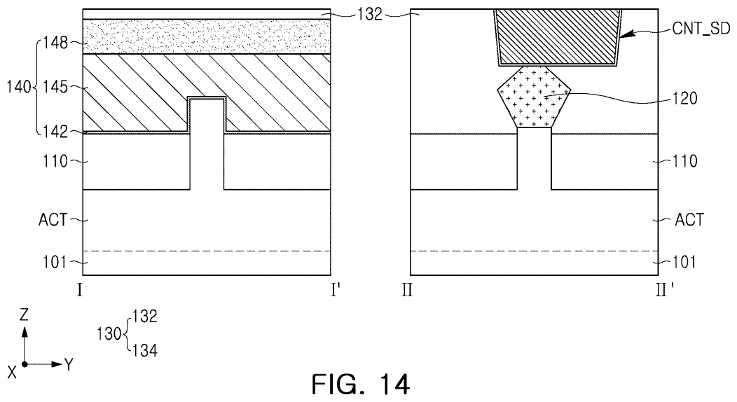

Referring to FIG. 14, the first lower interlayer insulating layer 132 may be patterned to form source/drain contact structures CNT_SD in contact with the source/drain region 120.

A desired (and/or alternatively predetermined) mask layer may be formed on the first lower interlayer insulating layer 132, and then openings, exposing an upper region of the source/drain region 120, may be formed using the mask layer. The desired (and/or alternatively predetermined) mask layer may be, for example, a photoresist layer.

The source/drain contact structures CNT_SD may be formed by filling a conductive material in the openings.

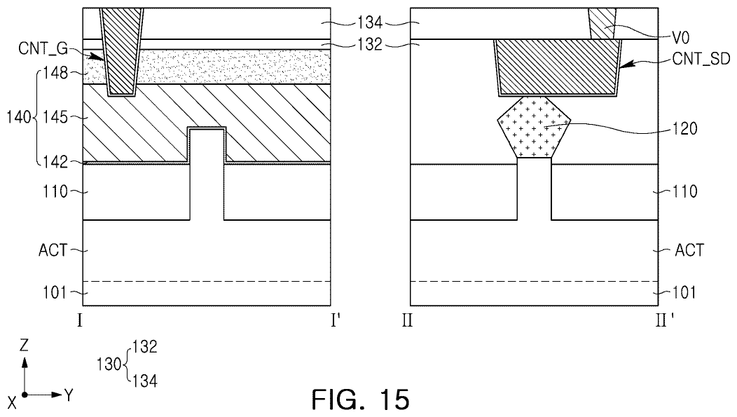

Referring to FIG. 15, a gate contact structure CNT_G, physically connected to the gate structure 140, and a via structure V0, physically connected to the source/drain contact structures CNT_SD, may be formed.

A second lower interlayer insulating layer 134 may be formed on the first lower interlayer insulating layer 132 and the source/drain contact structures CNT_SD. Thereafter, a desired (and/or alternatively predetermined) mask layer may be formed on the second lower interlayer insulating layer 134, and then openings, exposing at least a portion of the gate electrode layer 145, and openings, exposing at least a portion of the source/drain contact structure CNT_SD, may be formed using the mask layer.

The gate contact structure CNT_G and the via structure V0 may be formed by filling a conductive material in the openings.

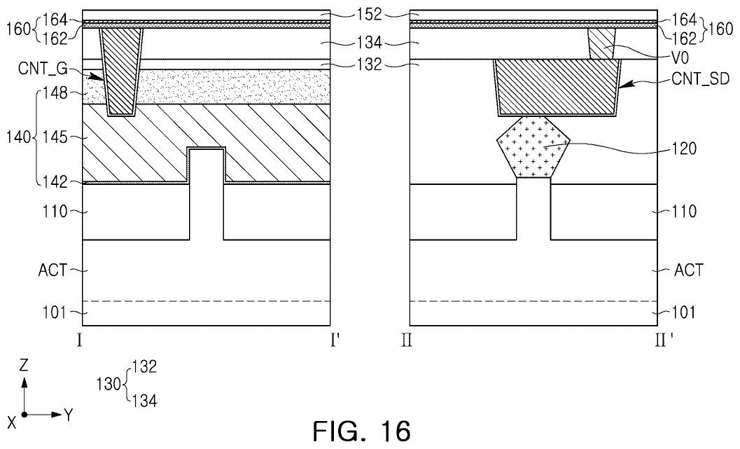

FIGS. 16 to 22 may be process diagrams of sequential processes of forming a back end of line (BEOL) of the semiconductor device 100 according to an example embodiment. FIG. 16 may be a process diagram following FIG. 15.

Referring to FIG. 16, etch stop layers 160 and a first upper interlayer insulating layer 152 may be sequentially formed on the second lower interlayer insulating layer 134.

A first etch stop layer 162 and a second etch stop layer 164, covering the gate contact structure CNT_G and the source/drain contact structures CNT_SD, may be sequentially formed on the second lower interlayer insulating layer 134. Each of the first and second etch stop layers 162 and 164 may be selected from the group consisting of aluminum oxide (Al₂O₃), aluminum nitride (AlN), hafnium oxide (HfO₂), zirconium oxide (ZrO₂), and silicon oxycarbide (SIOC). In the present example embodiment, the first etch stop layer 162 may include aluminum oxide (Al₂O₃), and the second etch stop layer 162 may include silicon oxycarbide (SIOC).

The first upper interlayer insulating layer 152, covering the etch stop layers 160, may be formed. The first upper interlayer insulating layer 152 may include, for example, at least one of oxide, nitride, and oxynitride.

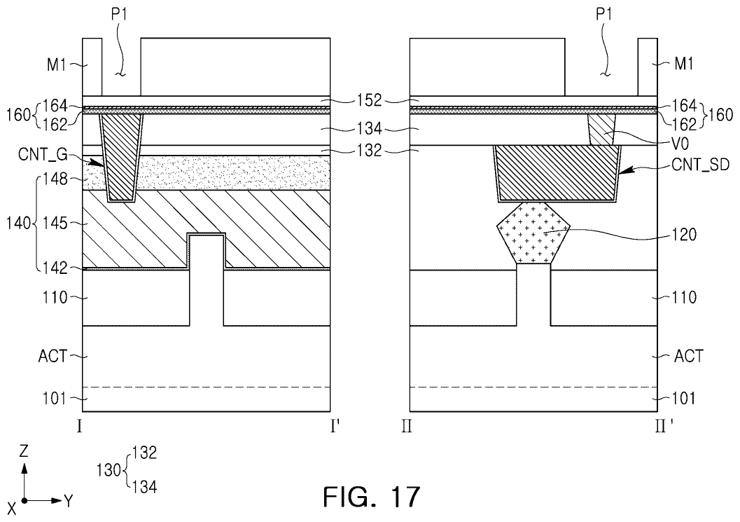

Referring to FIG. 17, a first mask layer M1 having a plurality of first open regions P1 may be formed on the first upper interlayer insulating layer 152.

The first mask layer M1 may be aligned such that the plurality of first open regions P1 are positioned on the gate contact structure CNT_G and the via structure V0.

The first mask layer M1 may be, for example, a photoresist layer. At least a portion of an upper surface of the first upper interlayer insulating layer 152 may be exposed by the first open region P1.

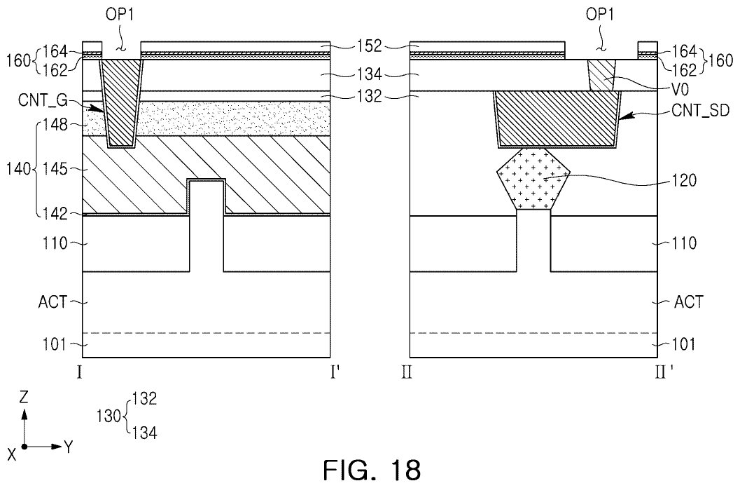

Referring to FIG. 18, the first upper interlayer insulating layer 152 may be patterned using the first mask layer M1.

The first upper interlayer insulating layer 152, exposed by the first open region P1, may be removed, and the etch stop layers 160, exposed by removing the first upper interlayer insulating layer 152, may be removed to form a first etched region OP1.

Referring to FIG. 1 together with FIG. 18, the first etched region OP1 may be in the form of a hole. In addition, a horizontal width of the first etched region OP1, formed on the gate contact structure CNT_G, may be greater than a horizontal width of the first etched region OP1, formed on the via structure V0.

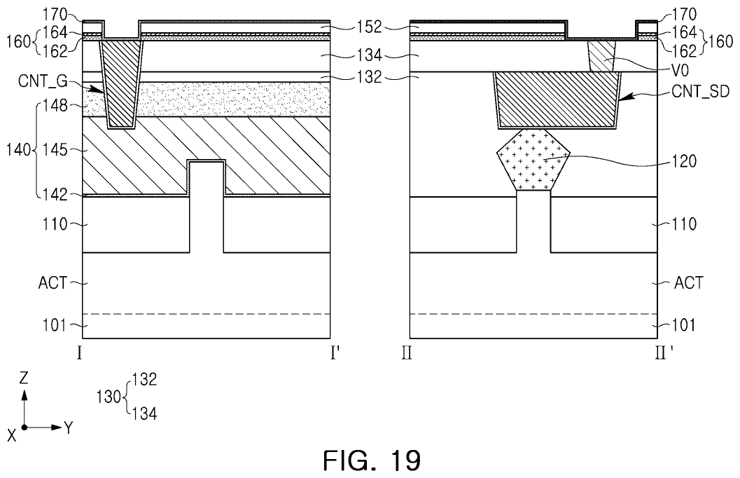

Referring to FIG. 19, a liner 170 may be formed on the first upper interlayer insulating layer 152.

The liner 170 may be conformally formed along the upper surface of the first upper interlayer insulating layer 152 and an external surface of the first etched region OP1. The liner 170 may include at least one of aluminum oxide (Al₂O₃), aluminum nitride (AlN), hafnium oxide (HfO₂), and zirconium oxide (ZrO₂).

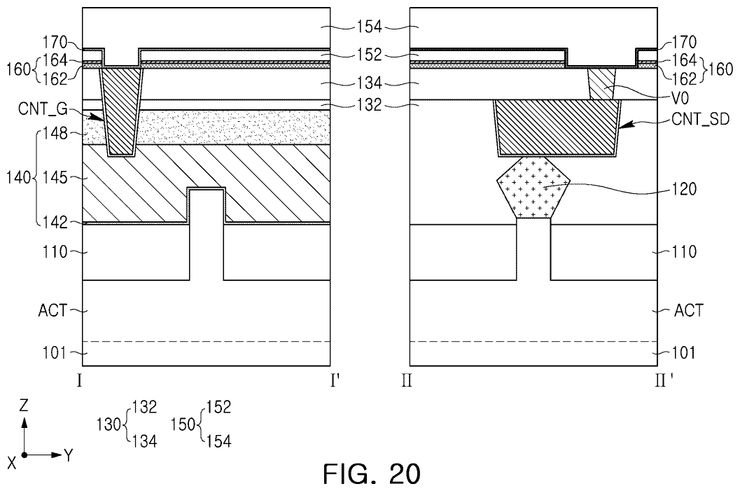

Referring to FIG. 20, a second upper interlayer insulating layer 154 may be formed on the liner 170.

The second upper interlayer insulating layer 154 may be formed by forming an insulating material on the liner 170 and performing a planarization process. The second upper interlayer insulating layer 154 may include a material the same as that of as the first upper interlayer insulating layer 152.

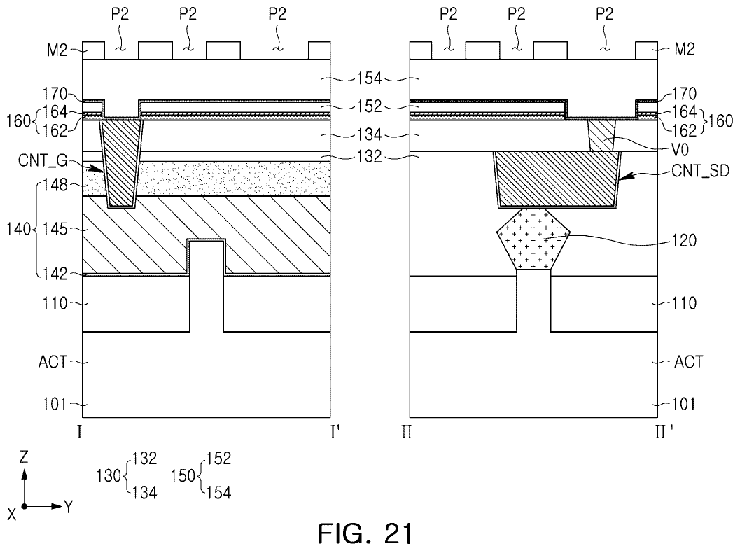

Referring to FIG. 21, a second mask layer M2, having a plurality of second open regions P2, may be formed on the second upper interlayer insulating layer 154.

The second mask layer M2 may be aligned such that at least a portion of the second open regions P2 is positioned on the first etched region OP1. In this case, at least a portion of the second open regions P2 may have a horizontal width substantially equal to a horizontal width of the first etched region OP1. Here, the horizontal width may refer to a horizontal width in a second direction, for example, a Y-direction (see FIGS. 1 and 2).

At least a portion of an upper surface of the second upper interlayer insulating layer 154 may be exposed by the second open region P2.

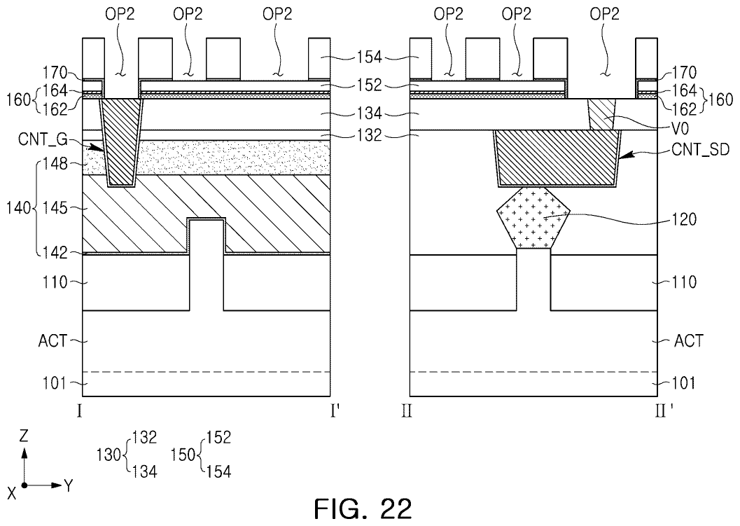

Referring to FIG. 22, the second upper interlayer insulating layer 154 may be patterned using the second mask layer M2.

The second upper interlayer insulating layer 154, exposed by the second open region P2, may be removed, and the insulating liner 170, exposed by removing the second upper interlayer insulating layer 152, may be removed to form a second etched region OP2.

Referring to FIG. 1 together with FIG. 22, the second etched region OP2 may be in the form of a line. In addition, a horizontal width of the second etched region OP2, formed on the gate contact structure CNT_G, may be greater than a horizontal width of the second etched region OP2, formed on the via structure V0. Here, the horizontal width may refer to a horizontal width in the second direction, for example, the Y-direction (see FIGS. 1 and 2).

Thereafter, the second etched region OP2 may be filled with a conductive material to form first interconnection lines 180, specifically, first to third line structures 181, 182, and 183 (see FIGS. 1 and 2).

Subsequently, although not illustrated, an interlayer insulating layer covering the first interconnection lines 180, on the second upper interlayer insulating layer 154, may be additionally formed, and an upper via passing through the interlayer insulating layer, the upper via connected to the first interconnection lines 180, and second interconnection lines, electrically connecting the first interconnection lines 180 to each other, may be formed on the interlayer insulating layer. If necessary, a process of forming an interlayer insulating layer, upper via, and interconnection lines may be repeated in the same manner.

According to example embodiments of inventive concepts, a semiconductor device may include interconnection lines respectively having a step in one direction to limit and/or prevent a short circuit between the interconnection lines.

Specifically, the semiconductor device according to inventive concepts may include interconnection lines having a step in a first direction (for example, an X-direction). Due to the step, levels of lowermost surfaces of the interconnection lines may be different from each other in at least one cross-sectional view among a plurality of cross-sectional views extending in a second direction (for example, a Y-direction), the plurality of cross-sectional views in a third direction (for example, a Z-direction). Accordingly, a sufficient separation distance may be secured between adjacent interconnection lines, thereby limiting and/or minimizing and/or preventing a short circuit.

While example embodiments have been shown and described above, it will be apparent to those skilled in the art that modifications and variations could be made without departing from the scope of inventive concepts as defined by the appended claims.

What is claimed is:

1. A semiconductor device comprising:
a substrate including an active region extending in a first direction;
a gate structure on the active region and intersecting the active region, the gate structure including a gate electrode and a gate capping layer on the gate electrode, the gate structure extending in a second direction, the second direction intersecting the first direction;
a source/drain region on the active region, the source/drain region on a side of the gate structure;
a contact structure on the source/drain region and electrically connected to the source/drain region;
a first insulating layer on the gate structure and the contact structure;
a gate contact structure passing through the first insulating layer and the gate capping layer of the gate structure, the gate contact structure electrically connected to the gate electrode of the gate structure;
a via structure passing through the first insulating layer, the via structure being electrically connected to the contact structure;
an etch stop layer on the first insulating layer and the gate contact structure;
a second insulating layer on the etch stop layer;
an insulating liner on the second insulating layer; and
interconnection lines on the first insulating layer, the interconnection lines including a first line, a second line, and a third line sequentially spaced apart in the second direction on the first insulating layer, wherein
each of the first line, the second line, and the third line include a line portion and an extension portion extending from the line portion in a third direction,
in each of the first line, the second line, and the third line, the line portion passes through the insulating liner and extends in the first direction on the second insulating layer,
the third direction is perpendicular to the first direction and the second direction, and
the extension portion of the first line, the extension portion of the second line, and the extension portion of the third line each pass through the second insulating layer and the etch stop layer and are electrically connected to a corresponding one of the gate contact structure and the via structure.

2. The semiconductor device of claim 1, wherein
the first line is a signal transmission line electrically connected to the gate electrode of the gate structure, and
the third line is a power transmission line electrically connected to the source/drain region.

3. The semiconductor device of claim 1, wherein
in each of the first line, the second line, and the third line, the line portion and the extension portion connected to the line portion include a same conductive material.

4. The semiconductor device of claim 1, wherein
in each of the first line, the second line, and the third line, a thickness of the extension portion is ⅕ to ⅓ of a thickness of the line portion connected to the extension portion.

5. The semiconductor device of claim 1, wherein
in each of the first line, the second line, and the third line, the extension portion has a cylindrical shape.

6. The semiconductor device of claim 1, wherein
a lower surface of the extension portion of the first line is in contact with an upper surface of the gate contact structure, and
in a cross-section in the third direction, which overlaps the upper surface of the gate contact structure, a level of the lower surface of the extension portion of the first line is lower than a level of a lower surface of the second line and a level of a lower surface of the third line.

7. The semiconductor device of claim 1, wherein
a lower surface of the extension portion of the third line is in contact with an upper surface of the contact structure, and
in a cross-section in the third direction, which overlaps the upper surface of the contact structure, a level of the lower surface of the third line is lower than a level of the lower surface of the first line and a level of the lower surface of the second line.

8. The semiconductor device of claim 1, wherein
a lower surface of the extension portion of the first line is in contact with an upper surface of the gate contact structure,
a lower surface of the extension portion of the third line is in contact with an upper surface of the contact structure,
in a first cross-section extending in the second direction, which overlaps the upper surface of the gate contact structure, a level of the lower surface of the first line is lower than a level of a lower surface of the second line and the lower surface of the third line, and
in a second cross-section extending in the second direction, which overlaps the upper surface of the contact structure, the lower surface of the third line is lower than the lower surface of the first line and the lower surface of the second line.

9. The semiconductor device of claim 8, wherein
the insulating liner is in contact with a side surface of the line portion of the first line on the second insulating layer and a side surface of the line portion of the third line on the second insulating layer,
in the first cross-section, the insulating liner extends from the side surface of the line portion of the first line to a space between the extension portion of the first line and the second insulating layer, and
in the second cross-section, the insulating liner extends from the side surface of the line portion of the third line to a space between the extension portion of the third line and the second insulating layer.

10. The semiconductor device of claim 8, wherein
in each of the first line, the second line, and the third line, a horizontal width of the line portion in the second direction gradually decreases as a distance to an upper surface of the extension portion, corresponding to the line portion, decreases.

11. The semiconductor device of claim 8, wherein
in each of the first line, the second line, and the third line, a horizontal width in the second direction of an upper region of the line portion is greater than a horizontal width in the second direction of the extension portion corresponding to the line portion, and
in each of the first line, the second line, and the third line, a lower surface of a portion of the upper region of the line portion is in contact with an upper surface of the insulating liner.

12. The semiconductor device of claim 8, wherein an external surface of the extension portion of the first line, an external surface of the extension portion of the second line, and an external surface of the extension portion of the third line are in contact with the second insulating layer and a corresponding side surface of the etch stop layer.

13. The semiconductor device of claim 8, further comprising:
a barrier layer covering a side surface of the line portion of the first line, a side surface of the line portion of the second line, and a side surface of the line portion of the third line, wherein
the barrier layer extends along a side surface of the extension portion of the first line, a lower surface of the extension portion of the first line, a side surface of the extension portion of the second line, a lower surface of the extension portion of the second line, a side surface of the extension portion of the third line, and a lower surface of the extension portion of the third line.

14. The semiconductor device of claim 1, wherein
the etch stop layer includes a plurality of etch stop layers, and
the plurality of etch stop layers include a first layer and a second layer on the first layer, and
a material of the second layer is different from a material of the first layer.

15. The semiconductor device of claim 1, further comprising:
a plurality of channel layers on the active region and spaced apart from each other in a vertical direction, wherein
the vertical direction is perpendicular to an upper surface of the substrate, and
the gate structure surrounds the plurality of channel layers.

16. A semiconductor device comprising:
a substrate including an active region extending in a first direction;
a gate structure on the active region and intersecting the active region, the gate structure extending in a second direction, the second direction intersecting the first direction;
a source/drain region on the active region, the source/drain region on a side of the gate structure;
a contact structure on the source/drain region and electrically connected to the source/drain region;
a via structure on the contact structure and electrically connected to the contact structure;
a gate contact structure on the gate structure and electrically connected to the gate structure;
a first signal transmission line structure including a first line portion extending in one direction across the gate structure and a first protrusion portion vertically protruding from a lower surface of the first line portion toward the gate contact structure, the first signal transmission line structure being on the gate structure; and
a power transmission line structure including an interconnection portion and an extension portion, the interconnection portion extending in the one direction across the gate structure and the contact structure, and the extension portion vertically extending from a lower surface of the interconnection portion toward the via structure, the power transmission line structure being on the contact structure.

17. The semiconductor device of claim 16, further comprising:
a second signal transmission line structure between the first signal transmission line structure and the power transmission line structure, the second signal transmission line structure including a second line portion extending in the one direction across the gate structure and the contact structure, the second signal transmission line being on the active region, wherein
a level of a lower surface of the second line portion of the second signal transmission line structure is higher than a level of a lower surface of the first protrusion portion of the first signal transmission line structure and a level of a lower surface of the extension portion of the power transmission line structure.

18. The semiconductor device of claim 17, wherein
the second signal transmission line structure further includes a second protrusion portion vertically protruding from the lower surface of the second line portion toward the via structure, on the contact structure,
an outer periphery of each of the first protrusion portion, the second protrusion portion, and the extension portion has a circular cross-section.

19. A semiconductor device comprising:
a substrate including an active region extending in a first direction;
a gate structure on the active region and intersecting the active region, the gate structure including a gate electrode and a gate capping layer on the gate electrode, the gate structure extending in a second direction, the second direction intersecting the first direction;
a source/drain region on the active region, the source/drain region on a side of the gate structure;
a contact structure on the source/drain region and electrically connected to the source/drain region;
a first insulating layer on the gate structure and the contact structure;
a gate contact structure passing through the first insulating layer and the gate capping layer of the gate structure, the gate contact structure electrically connected to the gate electrode of the gate structure;
a via structure passing through the first insulating layer, the via structure electrically connected to the contact structure;
an etch stop layer on the first insulating layer and the gate contact structure;
a second insulating layer on the etch stop layer;
an insulating liner on the second insulating layer; and
first interconnection lines on the first insulating layer and spaced apart from each other in the second direction, wherein
the first interconnection lines include a first line structure and a second line structure,
the first line structure includes a first line portion and a protrusion portion,
the first line portion is on the second insulating layer and extends in one direction across the gate structure,
the protrusion portion vertically protrudes from a lower surface of the first line portion, passes through the second insulating layer and the etch stop layer, and is in contact with the gate contact structure,
the second line structure includes an interconnection portion and an extension portion,
the interconnection portion is on the second insulating layer and extends in the one direction across the gate structure and the contact structure,
the extension portion vertically protrudes from a lower surface of the interconnection portion, passes through the second insulating layer and the etch stop layer, and is in contact with the via structure, and
outer peripheries of the protrusion portion of the first line structure and the extension portion of the second line structure have a circular cross-section.

20. The semiconductor device of claim 8, further comprising:
a barrier layer extending from a side surface of the first line portion to a side surface of the protrusion portion.
